(19) United States
(12) Patent Application Publication
(10) Pub. No.: US 2018/0166642 A1
(43) Pub. Date: Jun. 14, 2018

(54) QUANTUM DOT STRUCTURE AND MANUFACTURING METHOD, QUANTUM DOT LIGHT-EMITTING DIODE AND MANUFACTURING METHOD

(71) Applicant: Zaifeng Xie, Shenzhen (CN)

(72) Inventor: Zaifeng Xie, Shenzhen (CN)

(73) Assignee: AAC Technologies Pte. Ltd., Singapore city (SG)

(21) Appl. No.: 15/416,305

(22) Filed: Jan. 26, 2017

(30) Foreign Application Priority Data
Dec. 8, 2016 (CN) 201611120713.7

(51) Int. Cl. H01L 51/50; H01L 51/56; C09K 11/88

(52) U.S. Cl. CPC H01L 51/502; B82Y 20/00; C09K 11/883; H01L 51/56

(57) ABSTRACT

The present disclosures a quantum dot structure and a manufacturing method thereof, a quantum dot light-emitting diode (LED) and a manufacturing method thereof. The quantum dot structure includes a quantum dot core, a strain compensation layer wrapping the quantum dot core and a shell wrapping the strain compensation layer, wherein the degree of lattice match between the quantum dot core and the shell or the strain compensation layer is more than 88%.

### FIELD OF THE DISCLOSURE

The present disclosure relates to the technical field of light-emitting diodes and, specifically, to a quantum dot structure and a manufacturing method thereof, a quantum dot light-emitting diode (LED) and a manufacturing method thereof.

### BACKGROUND

Light-emitting diodes have been increasingly applied in modern display technology, and are advantageous over traditional light sources, such as low energy consumption, long service life, firmness, small size and quick conversion. Inorganic quantum dot light-emitting diodes are superior to organic light-emitting diodes and other light-emitting diodes, including stability, solution processability and outstanding color purity. Therefore, the quantum dot light-emitting diodes have been increasingly widely developed for use in the fields of display and light sources.

In the relevant art, there are a quite large number of unsaturated bonds on the quantum dot surface of a quantum dot light-emitting diode, and nano-particles thus produce surface defects to form many discrete surface state energy levels for capturing electron-hole pairs in a device, so that the fluorescent luminous efficiency of quantum dots is reduced. In order to solve this technical problem, it has been common practice to make a semiconductor material with wide energy bands into a shell of quantum dot cores to passivate and isolate surface states. This practice, though effective, is always very bad for manufacturing high-performance quantum dot light-emitting diodes due to stress generation and quantum dot collapse caused by lattice mismatch of quantum dots and shell semiconductor materials.

Therefore, it is desired to provide a quantum dot structure and a manufacturing method thereof, a quantum dot light-emitting diode (LED) and a manufacturing method thereof to overcome the aforesaid problems.

### BRIEF DESCRIPTION OF THE DRAWINGS

Many aspects of the embodiments can be better understood with reference to the following drawings. The components in the drawing are not necessarily drawn to scale, the emphasis instead being placed upon clearly illustrating the principles of the present disclosure. Moreover, in the drawings, like reference numerals designate corresponding parts throughout the several views.

FIG. 1 is a structural schematic diagram of a quantum dot light-emitting diode provided by the present disclosure; and

FIG. 2 is a structural schematic diagram of a quantum dot structure in a quantum dot light-emitting layer shown in FIG. 1.

### DETAILED DESCRIPTION

Reference will now be made to describe an exemplary embodiment of the present invention in detail.

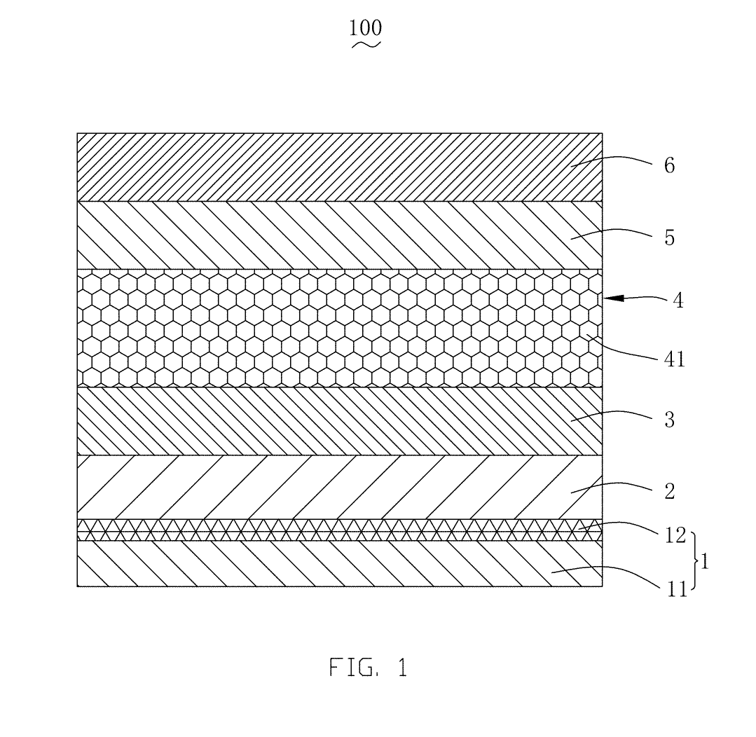

As shown in FIG. 1, a quantum dot light-emitting diode 100 includes a base plate 1, a hole injection layer 2, a hole transport layer 3, a quantum dot light-emitting layer 4, an electron transport layer 5 and a cathode 6 stacked in sequence.

The base plate 1 includes a substrate 11 and a conductive anode 12 deposited on the substrate 11. The substrate 11 is a rigid substrate or a flexible substrate, wherein the rigid substrate is made of glass, silicon wafer or other rigid material; and the flexible substrate is made of plastic, aluminum foil, ultrathin metal or ultrathin glass. The conductive anode 12 is made of ITO (Indium Tin Oxides), graphene, indium gallium zinc oxide or other conductive material, and is deposited on the surface of the substrate 11 by sputtering, evaporation and the like.

The hole injection layer 2 is an organic coating, and is formed by coating a PEDOT:PSS solution, wherein PEDOT is poly(3,4-ethylenedioxythiophene), and PSS is polystyrene sulfonate. The thickness of the hole injection layer 2 is 20-40 nm.

The hole transport layer 3 is also an organic coating and is formed by coating a mixed solution of polyvinylcarbazole and chlorotoluene. The thickness of the hole transport layer 3 is 10-30 nm.

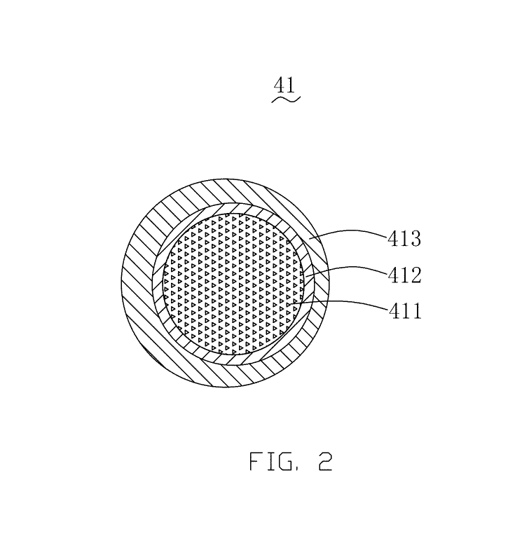

The quantum dot light-emitting layer 4 includes a plurality of quantum dot structures 41, and the thickness of the quantum dot light-emitting layer 4 is 20-50 nm, preferably 30 nm. Reference is made to FIG. 2, which is a structural schematic diagram of a quantum dot structure in the quantum dot light-emitting layer shown in FIG. 1. The quantum dot structure 41 includes a quantum dot core 411, a strain compensation layer 412 wrapping the quantum dot core 411 and a shell 413 wrapping the strain compensation layer 412. The degree of lattice match between the quantum dot core 411 and the shell 413 or the strain compensation layer is more than 88%.

At least one of the quantum dot core 411, the strain compensation layer 412 and the shell 413 is made of a semiconductor material, and the semiconductor material includes at least one of a Group I-VII compound, a Group II-VI compound, a Group III-V compound and a Group IV monomer.

In this embodiment, the quantum dot core 411 is made of the Group III-V compound, preferably at least one of InAs, InP, InN, GaN, InSb, InAsP, InGaAs, GaAs, GaP, GaSb, AlP, AlN and AlAs, and particularly preferably InP.

The strain compensation layer 412 is made of the Group II-VI compound or/and the Group III-V compound; preferably, the Group II-VI compound is at least one of ZnSe, ZnS and ZnO, and the Group III-V compound is at least one of GaNAs, GaP, GaInP, GaAsP, InGaAsP and InGaAlAs; and particularly preferably, the Group II-VI compound is ZnSe.

The shell 413 is made of the Group II-VI compound, preferably at least one of ZnSe, ZnS and ZnO, and particularly preferably ZnS.

According to the above preferred conditions, the quantum dot structure 41 is preferably an InP/ZnSe/ZnS multilayer structure having a radius of 2.4-2.8 nm, e.g., 2.6 nm. The lattice constant of the quantum dot core InP is 5.87 Å, the lattice constant of the shell ZnS is 5.41 Å, and the degree of lattice mismatch of the both is 7.8%, that is, the degree of lattice mismatch between the quantum dot core 411 and the shell 413 is small and is much smaller than 12%, so that excellent performance of the quantum dot structure 41 is guaranteed.

The electron transport layer 5 is made of metal oxide nano particles, which are selected from metal oxides of Group IIB or VA elements, e.g., ZnO or Sb2O3, etc., preferably ZnO. The electron transport layer 5 is deposited on the quantum dot light-emitting layer 4 by a spin-coating process, and has a thickness of 10-30 nm.

The cathode 6 is made of Al and deposited on the electron transport layer 5 by vacuum thermal evaporation, and the cathode 6 is electrically connected with the conductive anode 12. The thickness of the cathode 6 is 100-180 nm, preferably 150 nm.

The present disclosure further provides a manufacturing method of a quantum dot structure, including the following steps:

step S1: adding In(MA)x and P(TMS)3 into an octadecene solution as a quantum dot precursor, and reacting for 1-10 min by thermal injection at a temperature of 280-320° C. to obtain an InP quantum dot core, wherein In(MA)x refers to an indium myristate compound, P(TMS)3 refers to tri(trimethylsilyl)phosphorane, and the both serve as a precursor for quantum dot synthesis;

step S2: providing a zinc source as a strain compensation layer precursor, mixing the InP quantum dot core, the strain compensation layer precursor and trioctylphosphine selenium, and reacting for 20-50 min by thermal injection at a temperature of 260-300° C. to obtain an InP/ZnSe structure, wherein ZnSe forms a strain compensation layer wrapping the InP quantum dot core,

wherein, the zinc source serving as the strain compensation layer precursor is zinc acetate crystal; and

step S3: providing a zinc source as a shell precursor, mixing the InP/ZnSe structure, the shell precursor and cyclohexyl isothiocyanate, and reacting for 10-30 min by thermal injection at a temperature of 260-300° C. to obtain an InP/ZnSe/ZnS structure, wherein ZnS forms a shell wrapping the InP/ZnSe structure;

Wherein the zinc source serving as the shell precursor is zinc acetate crystal.

The present disclosure further provides a manufacturing method of a quantum dot light-emitting diode, including the following steps:

step S1′: forming a hole injection layer 2 on a base plate 1;

specifically, step S1′ includes pretreatment of the base plate: firstly, ultrasonically cleaning the base plate 1 with acetone or an isopropyl amine solution; then heating the base plate 1 at a temperature of 120-200° C. and baking the base plate 1 for 20-50 min; transferring the base plate 1 to a plasma cleaner, and introducing Ar/O2 gas under the radio-frequency action of 13.56 MHZ to remove organic matters from the base plate for 10-20 min;

coating the pretreated base plate 1 with a layer of PEDOT:PSS mixed solution, followed by spin-coating for 1-3 min at a rate of 4500 rpm, and then heating the base plate 1 to 120-150° C. to form a PEDOT:PSS uniform film having a thickness of 30 nm, i.e., the hole injection layer 2;

step S2′: forming a hole transport layer 3 on the hole injection layer 2;

specifically, spin-coating the hole injection layer 2 with a mixed solution of PVK (polyvinylcarbazole) and chlorotoluene, and heating the hole injection layer 2 to form a PVK polymer film having a thickness of 20 nm, i.e., the hole transport layer 3;

step S3′: depositing quantum dot structures 41 on the hole transport layer 3 to form a quantum dot light-emitting layer 4;

specifically, spin-coating the hole transport layer 3 with the formed quantum dot structures 41 to form the quantum dot light-emitting layer 4 having a thickness of 30 nm; and

step S4′: forming an electron transport layer 5 and a cathode 6 on the quantum dot light-emitting layer 4 in sequence;

specifically, depositing the electron transport layer 5 having a thickness of 30 nm on the quantum dot light-emitting layer 4 by a sol-gel process, the electron transport layer 5 being made of ZnO nano particles; then depositing the cathode 6 having a thickness of 150 nm on the electron transport layer 5 by vacuum thermal evaporation, the cathode 6 being made of Al; and electrically connecting the cathode with a conductive anode 12.

Compared with the relevant art, the quantum dot structure provided by the present disclosure has the advantages that pressure application brought when the shell material is produced can be effectively eliminated by adding the strain compensation layer under the condition that the degree of lattice match between the quantum dot core and the shell or the strain compensation layer is more than 88%, thereby meeting the low stress requirement of the quantum dot core and improving the performance of the light-emitting diode manufactured by using the quantum dot structure; the quantum dot structure is preferably an InP/ZnSe/ZnS multilayer structure, the lattice constant of the quantum dot core InP is 5.87 Å, the lattice constant of the semiconductor shell ZnS is 5.41 Å, and the degree of lattice mismatch of the both is 7.8%, that is, the degree of lattice mismatch between the quantum dot core and the shell is small, so that the performance of the quantum dot structure is further improved; the adopted semiconductor material is a nontoxic semiconductor material, thereby reducing the pollution to environment; the quantum dot core is formed uniformly by adopting a thermal injection process, and the production states of crystal particles are substantially kept consistent, so that monodispersity of the quantum dot core is guaranteed; and similarly, the strain compensation layer and the shell are also formed by the thermal injection process, so that the performance of the resultant quantum dot structure is excellent.

It is to be understood, however, that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms in which the appended claims are expressed.

1. A quantum dot structure, comprising:
a quantum dot core,
a strain compensation layer wrapping the quantum dot core, and
a shell wrapping the strain compensation layer,
wherein the degree of lattice match between the quantum dot core and the shell or the strain compensation layer is more than 88%.

2. The quantum dot structure as described in claim 1, wherein at least one of the quantum dot core, the strain compensation layer and the shell is made of a semiconductor material.

3. The quantum dot structure as described in claim 2, wherein the semiconductor material comprises at least one of a Group I-VII compound, a Group II-VI compound, a Group III-V compound and a Group IV monomer.

4. The quantum dot structure as described in claim 16, wherein the Group III-V compound comprises at least one of InAs, InP, InN, GaN, InSb, InAsP, InGaAs, GaAs, GaP, GaSb, AlP, AlN and AlAs.

5. The quantum dot structure as described in claim 4, wherein the Group III-V compound is InP.

6. The quantum dot structure as described in claim 3, wherein the strain compensation layer is made of the Group II-VI compound or/and the Group III-V compound.

7. The quantum dot structure as described in claim 6, wherein the Group II-VI compound comprises at least one of ZnSe, ZnS and ZnO, and the Group III-V compound is at least one of GaNAs, GaP, GaInP, GaAsP, InGaAsP and InGaAlAs.

8. The quantum dot structure as described in claim 7, wherein the Group II-VI compound is ZnSe.

9. The quantum dot structure as described in claim 3, wherein the shell is made of the Group II-VI compound.

10. The quantum dot structure as described in claim 9, wherein the Group II-VI compound comprises at least one of ZnSe, ZnS and ZnO.

11. The quantum dot structure as described in claim 1, wherein the quantum dot core is made of InP, the strain compensation layer is made of ZnSe, and the shell is made of ZnS.

12. The quantum dot structure as described in claim 11, wherein the radius of the quantum dot structure is 2.4-2.8 nm.

13. A manufacturing method of a quantum dot structure, comprising the following steps:
adding In(MA)x and P(TMS)3 into an octadecene solution as a quantum dot precursor, and reacting for 1-10 min by thermal injection at a temperature of 280-320° C. to obtain an InP quantum dot core;
providing a zinc source as a strain compensation layer precursor, mixing the InP quantum dot core, the strain compensation layer precursor and trioctylphosphine selenium, and reacting for 20-50 min by thermal injection at a temperature of 260-300° C. to obtain an InP/ZnSe structure, wherein ZnSe forms a strain compensation layer wrapping the InP quantum dot core; and
providing a zinc source as a shell precursor, mixing the InP/ZnSe structure, the shell precursor and cyclohexyl isothiocyanate, and reacting for 10-30 min by thermal injection at a temperature of 260-300° C. to obtain an InP/ZnSe/ZnS structure, wherein ZnS forms a shell wrapping the InP/ZnSe structure.

14. A quantum dot light-emitting diode, comprising:
a base plate,
a hole injection layer,
a hole transport layer,
a quantum dot light-emitting layer,
an electron transport layer, and
a cathode stacked on the base plate in sequence,
wherein the quantum dot light-emitting layer comprises a plurality of quantum dot structures, each quantum dot structure comprises a quantum dot core, a strain compensation layer wrapping the quantum dot core and a shell wrapping the strain compensation layer; and the degree of lattice match between the quantum dot core and the shell or the strain compensation layer is more than 88%.

15. A manufacturing method of a quantum dot light-emitting diode, comprising the following steps:
providing a base plate, and forming a hole injection layer on the base plate;
forming a hole transport layer on the hole injection layer;
depositing a plurality of quantum dot structures on the hole transport layer to form a quantum dot light-emitting layer, wherein each quantum dot structure comprises a quantum dot core, a strain compensation layer wrapping the quantum dot core and a shell wrapping the strain compensation layer, and the degree of lattice match between the quantum dot core and the shell or the strain compensation layer is more than 88%; and
forming an electron transport layer and a cathode on the quantum dot light-emitting layer in sequence.

16. The quantum dot structure as described in claim 3, wherein the quantum dot core is made of a Group III-V compound.

17. The quantum dot structure as described in claim 10, wherein the Group II-VI compound is ZnS.
